(19) United States
(12) Patent Application Publication
(10) Pub. No.: US 2018/0070459 A9
(43) Pub. Date: Mar. 8, 2018

(54) REMOTE CONTROLLER SHELL, REMOTE CONTROLLER, DISPLAY SYSTEM AND CONTROL SYSTEM

(71) Applicant: BOE TECHNOLOGY GROUP CO., LTD., Beijing (CN)

(72) Inventors: Yongda MA, Beijing (CN); Yong QIAO, Beijing (CN); Jianbo XIAN, Beijing (CN)

(21) Appl. No.: 15/501,458

(22) PCT Filed: Nov. 16, 2015
(86) PCT No.: PCT/CN2015/094724

§ 371 Date: Feb. 3, 2017

(30) Foreign Application Priority Data
Jun. 19, 2015 (CN) 201520431817.4

(51) Int. Cl. H05K 5/00; H05K 5/02; H05K 7/14; H01H 13/86

(52) U.S. Cl. CPC H05K 5/0017; H01H 13/86; H05K 7/1427; H05K 5/0217

(57) ABSTRACT

The present disclosure relates to the field of display technologies, and specifically relates to a remote controller shell, a remote controller, a display system and a control system. The shell includes a control surface provided with at least one function key and a holding surface disposed opposite to the control surface, wherein at least part of the control surface is, a curved surface structure. Full thought is given to a position where a user holds the remote controller, the control surface is designed to be a curved surface structure, so that a top surface area (an intrados) of the function key is increased, thereby making it convenient for the user's thumb operation. Alternatively further, the holding surface is also designed to be a curved surface structure, thereby making it convenient for holding (an extrados) and ensuring a grip comfort.

### CROSS REFERENCE TO RELATED APPLICATIONS

This application is a National Stage Entry of PCT/CN2015/094724 filed Nov. 16, 2015, which claims the benefit and priority of Chinese Patent Application No. 201520431817.4 filed Jun. 19, 2015, the disclosures of which are incorporated herein in their entirety as part of the present application.

### BACKGROUND

The present disclosure pertains to the field of display technologies, and specifically relates to a remote controller shell, a remote controller, a display system, and a control system.

A remote controller is a device used for providing a remote control of mechanical devices or apparatuses, which generally includes an integrated circuit and function keys used for generating different control commands.

The grip comfort of existing remote controllers is not good. To improve the grip comfort, sizes of the remote controllers need to be properly reduced, meanwhile, top surface areas of the function keys are correspondingly reduced, which is inconvenient for users' pressing operation, and distance that the thumb needs to move for pressing function keys differ greatly.

### BRIEF DESCRIPTION

The present disclosure provides a remote controller shell, a remote controller, a display system, and a control system, wherein the remote controller is convenient for being held by a user, and a top surface area of a function key is increased, thereby making it convenient for the user's press control to the function key.

A technical solution adopted in the present disclosure is the remote controller, including: the remote controller shell, and a circuit board and a signal emission source disposed inside the remote controller shell.

The remote controller shell includes a control surface provided with a plurality of function keys and a holding surface disposed opposite to the control surface, wherein at least a part of the control surface is a curved surface structure.

In one example, the holding surface and the control surface are straight-line curved surface structures.

Optionally, a straight-line generatrix forming a straight-line curved surface of the holding surface and a straight-line generatrix forming a straight-line curved surface of the control surface have an identical movement locus.

Optionally, the straight-line generatrix forming the straight-line curved surface of the holding surface and the straight-line generatrix forming the straight-line curved surface of the control surface have different movement loci, and the movement locus of the straight-line generatrix of the straight-line curved surface of the holding surface includes a curve segment and a straight line segment.

Optionally, the straight-line generatrix forming the straight-line curved surface of the holding surface and the straight-line generatrix forming the straight-line curved surface of the control surface have different movement loci, and the movement locus of the straight-line generatrix of the straight-line curved surface of the control surface includes a concave curve segment and a convex curve segment.

In one example, the holding surface and the control surface are curvilinear curved surface structures.

Optionally, a curvilinear generatrix of a curvilinear curved surface of the holding surface and a curvilinear generatrix of a curvilinear curved surface of the control surface respectively have at least two curves connected tangentially.

Optionally, the curvilinear generatrix of the curvilinear curved surface of the holding surface and the curvilinear generatrix of the curvilinear curved surface of the control surface include, respectively, curves and straight lines, or straight lines having different slopes.

Optionally, the curvilinear generatrix of the curvilinear curved surface of the holding surface and the curvilinear generatrix of the curvilinear curved surface of the control surface include curves having different curvatures.

In one example, either one of the holding surface and the control surface is a straight-line curved surface structure, the other one is a curvilinear curved surface structure, and as a whole, the straight-line curved surface and the curvilinear curved surface have a consistent concave-convex trend.

In one example, the holding surface is a plane surface structure, and the control surface is a curved surface structure.

Optionally, the control surface is a straight-line curved surface structure or a curvilinear curved surface structure, and a cambered surface of the straight-line curved surface or the curvilinear curved surface is inwardly concave relative to the plane surface structure.

Optionally, in the control surface, a curved surface radian of the curved surface structure ranges from 0 rad to π rad.

Optionally, an upper surface of the function key has a same curved surface curvature as that of a settings area of the control surface provided with the function key.

Optionally, a contact part between the function key and a circuit board inside the shell is formed of an elastic material.

Optionally, the function key is wholly formed of an elastic material, or merely a key base of the function key in contact with the circuit board is formed of an elastic material.

Optionally, the upper surface of the function key is higher than a curved surface of the settings area of the control surface.

Optionally, a height that the upper surface of the function key is higher than the curved surface of the settings area of the control surface is equal to a distance that the function key needs to be pressed down for proper functioning.

A remote controller includes the remote controller shell.

A display system includes the remote controller.

A control system includes the remote controller.

Beneficial effects of the present disclosure are as below: full thought is given to a position where a user holds the remote controller, the control surface is designed to be a curved surface structure, so that a top surface area of a function key is increased, thereby making it convenient for the user's thumb operation. Alternatively further, the holding surface is also designed to be a curved surface structure, thereby making it convenient for holding and ensuring a holding comfort.

### BRIEF DESCRIPTION OF THE DRAWINGS

FIG. 1 is a schematic structural diagram of a remote controller shell according to at least one embodiment of the present disclosure;

FIG. 2 is a schematic structural diagram of a function key in the remote controller provided in FIG. 1;

FIG. 3 is a schematic structural diagram of a remote controller shell according to at least one embodiment of the present disclosure; and

FIG. 4 is a schematic structural diagram of a remote controller shell according to at least one embodiment of the present disclosure.

### DETAILED DESCRIPTION

In order that those skilled in the art better understand the technical solution of the present disclosure, the following further describes in detail the remote controller shell, the remote controller, the display system, and the control system of the present disclosure with reference to the accompanying drawings and embodiments. It is to be known that the accompanying drawings in the following description merely involve with some embodiments of the present disclosure, but not limit the present disclosure. Persons of ordinary skill in the art may still derive other drawings from these accompanying drawings without creative efforts.

A technical thought of the present disclosure is as below: a control surface of a handheld remote controller is designed, at least in part, to be a curved surface structure according to ergonomics, thereby making it convenient for holding the remote controller by a user, and a top surface area of a function key is increased, thereby making it convenient for the user's press control over the function key.

This embodiment provides a remote controller shell (hereinafter referred to as the shell).

In some embodiments, the shell includes a holding surface and a control surface disposed oppositely (herein a surface provided with one or more function keys is the control surface, and a surface opposite to the control surface is the holding surface), wherein a signal emission source is matched with a signal reception source of an apparatus or device which is remotely controlled by a remote controller.

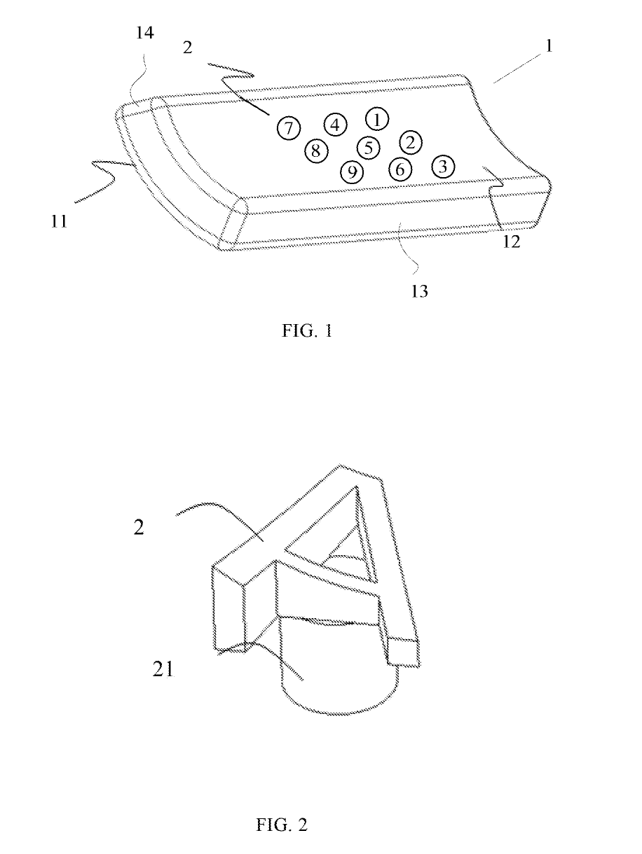

In some embodiments, the holding surface and the control surface are straight-line curved surface structures, and a straight-line curved surface of the holding surface 11 and a straight-line curved surface of the control surface 12 have an identical straight-line generatrix with an identical movement locus. Herein, a line whose movement locus produces a curved surface is named as a generatrix, and the straight-line curved surface refers to a curved surface formed by the movement locus of the straight-line generatrix moving along a segment of smooth curved line. As shown in FIG. 1, in the shell 1 of the remote controller, the holding surface 11 (namely, a lower surface of the remote controller shell) is arc-shaped, the control surface 12 (namely, an upper surface of the remote controller shell) is arc-shaped, and the control surface 12 is provided with function keys 2.

In the remote controller shell in this embodiment, the holding surface 11 and the control surface 12 have a consistent concave-convex trend, namely, the straight-line generatrix forming the straight-line curved surface of the holding surface and the straight-line generatrix forming the straight-line curved surface of the control surface have movement loci with an identical trend. In the remote controller shell in FIG. 1, the control surface 12 is inwardly concave, and the holding surface 11 is outwardly convex.

Optionally, a curved surface radian of a straight-line curved surface or a curvilinear curved surface ranges from 0 rad to π rad. Meanwhile, two waist surfaces connecting the holding surface 11 and the control surface 12 may be plane surfaces (to some extent, the plane surface may be regarded as a curved surface whose curvature is 0) or curved surfaces, which is not limited herein. For example, the waist surface may be a plane surface (such as a first waist surface 13 outwards a paper surface in FIG. 1) perpendicular to a surface edge tangent of the holding surface 11 or the control surface 12, or a plane surface (such as a second waist surface 14 inwards the paper surface in FIG. 1) tilted to the surface edge tangent of the holding surface 11 and the control surface 12.

To achieve function selection, as shown in FIG. 2, the control surface 12 is provided with a plurality of function keys 2, and an upper surface of the function key 2 has a same curved surface curvature as that of a settings area of the control surface 12 provided with the function keys 2. The settings area includes an area of the control surface occupied by the function keys, and may further include an area around the area of the control surface occupied by the function keys. It is easy to understand that under a premise of a fact that an orthogonal projection area is the same, a surface area of a curved surface is greater than or equal to a surface area of a plane surface. Therefore, the cambered control surface 12 in this embodiment is provided with function keys 2, which is advantageous to increasing the surface area of the control surface 12 and increasing sizes and top surface areas of the function keys 2, thereby making it convenient for the user's thumb pressing operation, meanwhile, the function keys being disposed on the inwardly concave cambered control surface 12 ensures that a distance difference of the user's thumb moving among function keys 2 during operation on the function keys 2 to be reduced, thereby improving an operation comfort degree.

To further improve the operation comfort degree, a contact part between the function key 2 and a circuit board inside the shell includes an elastic material. Optionally, the function key 2 is wholly formed of an elastic material, or merely a key base 21 of the function key 2 in contact with the circuit board is formed by an elastic material, and other parts are formed by using an inelastic material. When the function key 2 is partly formed by using an inelastic material, a stroke of pressing the function key 2 may be further reduced to a certain extent, which is advantageous to the pressing operation of the function key 2.

Meanwhile, to better achieve pressing the function key 2, the upper surface of the function key 2 is higher than the curved surface of the area corresponding to the control surface 12. As shown in FIG. 2, the upper surface of the function key 2 is a cambered surface which has a same radian as the curved surface of the control surface 12, and the upper surface of the function key 2 is higher than the control surface 12 when it is assembled into the remote controller. Optionally, a height that the upper surface of the function key 2 is higher than the curved surface of the area corresponding to the control surface 12 is equal to a distance that the function key 2 needs to be pressed for proper functioning.

For the hyperboloidal remote controller shell in this embodiment, full thought is given to a position where a user holds the remote controller, both the control surface and the holding surface are designed to be curved surface structures, which not only makes it convenient for holding (an extrados) and ensures a holding comfort, but also increases a top surface area (an intrados) of the function key and makes it convenient for the user's thumb operation.

This embodiment provides a remote controller shell, which differs from the above embodiment in that the holding surface 11 and the control surface 12 are different, in structure, from those in the above embodiment.

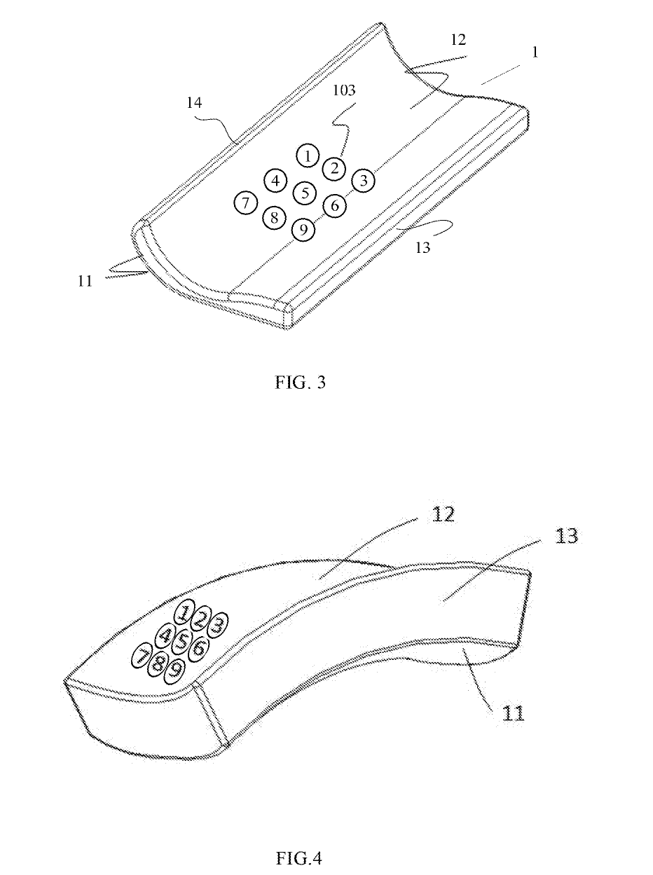

As shown in FIG. 3, in some embodiments, the holding surface 11 and the control surface 12 of the remote controller shell are straight-line curved surface structures, but a straight-line generatrix of the holding surface 11 and a straight-line generatrix of the control surface 12 have different movement loci. The movement locus of the straight-line generatrix of the holding surface 11 includes a combination of a curve segment and a straight line segment, and the movement locus of the straight-line generatrix of the control surface 12 includes a combination of a concave curve segment and a convex curve segment.

In some embodiments, in the structure of the remote controller shell corresponding to FIG. 3, the holding surface 11 and the control surface 12 have inconsistent concave-convex trends. Specifically, the holding surface 11 includes a plane surface and a curved surface connected tangentially, wherein the plane surface part serves as a part gripped by a thumb of a palm, and the curved surface part serves as a part gripped by other four fingers of the palm. The control surface 12 includes two curved surfaces having opposite cambered surface centers and connected tangentially, wherein the curved surface corresponding to the thumb part of the palm is outwardly convex so that the control surface 12 comes into contact with a thumb root to provide a better support for the thumb and a control comfort degree. The curved surface corresponding to the four fingers part is inwardly concave, and the curved surface part serves as arrangement layout of the function keys 2, facilitates an operation of a thumb tip pressing the function keys 2, and improves a comfort level of the function keys 2.

The plane surface part serving as a palm holding part may be designed on the right (for example, designed as the part outwards the paper surface in FIG. 3 for most users) or on the left (for example, designed as the part inwards the paper surface in FIG. 3 for left-handed users) according to users' habits, which is not limited herein.

In the remote controller shell of this embodiment, the upper surface of the function key 2 has a same curved surface curvature as that of a settings area of the control surface 12 provided with the function key 2, thereby increasing the top surface area of the function key 2 and making it convenient for operation.

In the remote controller shell of this embodiment, the structure and the material selected for the function key 2 are the same as those selected for the function key 2 in the foregoing embodiment, and thus their detailed descriptions are omitted herein.

Meanwhile, it is to be understood that in the remote controller shell of this embodiment, the movement loci for forming the straight-line curved surface of the holding surface 11 and the straight-line curved surface of the control surface 12 are not limited to the combination illustrated in FIG. 3. According to different application scenarios, the movement loci for forming the straight-line curved surface of the holding surface 11 and the straight-line curved surface of the control surface 12 may be respectively designed to be constituted by curved lines or straight lines of different segments, or may be designed to be constituted by a combination of curved lines having different curvatures of different segments, which is not limited herein.

For the hyperboloidal remote controller shell in this embodiment, full thought is given to a position where a user holds the remote controller, both the control surface and the holding surface are designed to be of different curved surface shapes, which not only makes it convenient for holding (an extrados) and ensures a hold comfort, but also increases a top surface area (an intrados) of the function key and makes it convenient for the user's thumb operation.

This embodiment provides a remote controller shell, which differs from the above embodiment in that the holding surface 11 and the control surface 12 are different, in structure, from the above embodiment.

As shown in FIG. 4, in some embodiments, the holding surface 11 and the control surface 12 of the remote controller shell are curvilinear curved surface structures, and a curvilinear generatrix of the holding surface 11 and a curvilinear generatrix of the control surface 12 respectively have at least two curved lines connected tangentially. Herein, a line whose movement locus generates a curved surface is known as a generatrix, and the curvilinear curved surface refers to a curved surface formed by the movement of the curvilinear generatrix.

In this embodiment, the curvilinear generatrix used for forming the holding surface 11 and the curvilinear generatrix used for forming the control surface 12 have two identical curve segments (which may be regarded as one curve segment having an extreme value point, namely a point connecting two curve segments) connected tangentially are taken as an example. As shown in FIG. 4, the holding surface 11 of the remote controller shell is inwardly concave and the control surface 12 is outwardly convex, thus a middle part of the remote controller shell is convex towards the control surface 12 relative to two ends of the remote controller shell, so that the remote controller shell may be more conveniently held in a palm.

Meanwhile, in FIG. 4, the function keys 2 are arrayed near to an end of the curved surface of the control surface 12. In view of a fact that the layout of the function keys 2 is in the same direction with fonts of digital IDs or letter IDs of the function keys 2, particularly preferably close to an end of an inner side of a thumb, namely an end close to a human body when the remote controller shell is in use (this rule is applicable to both right-handed users of majority and left-handed users). Therefore, an operation of a thumb tip pressing the function keys 2 may be facilitated, and a comfort level of pressing the function keys 2 may be improved.

Identical to the foregoing embodiments, in the remote controller shell of this embodiment, the upper surface of the function key 2 has a same curved surface curvature as that of the settings area of the control surface provided with the function key, thereby increasing the topside surface area of the function key 2 and making it convenient for operation.

In the remote controller shell of this embodiment, the structure and the material selected for the function key 2 are the same as those selected for the function key 2 in the embodiment 1, and thus their detailed descriptions are omitted herein.

Meanwhile, it is to be understood that for the remote controller shell of this embodiment, the curvilinear generatrices used for forming the curvilinear curved surface of the holding surface 11 and the curvilinear curved surface of the control surface 12 are not limited to the two curvilinear generatrices illustrated in FIG. 4, and the movement loci of the curvilinear generatrices are not limited to what are illustrated in FIG. 4. According to different application scenarios, the curvilinear generatrices for forming the curvilinear curved surface of the holding surface 11 and the curvilinear curved surface of the control surface 12 may be respectively designed to include a combination of different curved lines or straight lines, or may be designed to include a combination of curved lines having different curvatures of different segments, which is not limited herein.

For the hyperboloidal remote controller shell in this embodiment, full thought is given to a position where a user holds the remote controller, both the control surface and the holding surface are designed to be curvilinear curved surface structures, which not only makes it convenient for holding and ensures a grip comfort, but also increases the top surface area of the function key and makes it convenient for the user's thumb operation.

This embodiment provides a remote controller shell, which differs from any one of the above embodiments in that the holding surface and the control surface are different, in structure, from those in the above embodiments.

Either one of the holding surface 11 and the control surface of the remote controller shell is a straight-line curved surface structure, the other one is a curvilinear curved surface structure, and as a whole, the straight-line curved surface and the curvilinear curved surface have a consistent concave-convex trend.

In the remote controller shell according to any one of the foregoing embodiments, either one of the holding surface and the control surface is a straight-line curved surface structure and the other one is a curvilinear curved surface structure, which not only makes it convenient for holding and ensures a holding comfort, but also increases the top surface area of the function key and makes it convenient for the user's thumb operation.

This embodiment provides a remote controller shell, which differs from any one of the above embodiments in that the holding surface and the control surface are different, in structure, from those in the above embodiments.

In some embodiments, the control surface is a curved surface structure, and the holding surface is a plane surface structure. The curved surface structure of the control surface may be a straight-line curved surface structure or a curvilinear curved surface structure, and a cambered surface of the straight-line curved surface or the curvilinear curved surface is inwardly concave relative to the plane surface structure.

In the remote controller shell according to any one of the foregoing embodiments, when the control surface is a straight-line curved surface structure or a curvilinear curved surface structure, the top surface area of the function key is increased and the user's thumb operation is made convenient.

This embodiment provides a remote controller which includes a remote controller shell (hereinafter referred to as the shell), and a circuit board and a signal emission source disposed inside the shell.

This embodiment provides a display system, including the remote controller in the foregoing embodiments.

The display system includes a display apparatus, an STB (Set Top Box) and a relevant DVD apparatus, an audio device and so on.

Compared with a remote controller in the prior art, the remote controller in the display system implements an objective that when a user holds the remote controller at the same holding position for thumb operation, a distance from the thumb tip to each function key is approximately equal, and the top surface area of the function key is increased while a compact size of the remote controller is taken into account, thereby making it convenient for operation.

This embodiment provides a control system, including the remote controller according to any one of the foregoing embodiments.

It is easily understood that the remote controller in the present disclosure is not only applicable to the display system illustrated in this embodiment, but also applicable to other various electronic products such as an air conditioning device needing a remote control, or even a camera, a projector and the like, and a variety of daily use products such as an automatic laundry rack, an automatic curtain, a toy car or a toy plane and the like, wherein a signal emission source is matched with a signal reception source of an apparatus or a device which is remotely controlled by the remote controller. Of course, further, the holding surface may also be designed to be a curved surface structure, thereby making it convenient for gripping and ensuring a grip comfort.

It is to be understood that the foregoing embodiments are merely exemplary embodiments employed to describe the principle of the present disclosure. However, the present disclosure is not limited to this. To those of ordinary skill in the art, various modifications and improvements may be made without departing from the spirit and essence of the present disclosure, and these modifications and improvements are also deemed to be within the scope of protection of the present disclosure.

1. A remote controller shell, comprising:
a control surface provided with at least one function key; and
a holding surface disposed opposite to the control surface, wherein at least part of the control surface is a curved surface structure.

2. The remote controller shell according to claim 1, wherein the holding surface and the control surface are curved surface structures.

3. The remote controller shell according to claim 2, wherein the holding surface and the control surface are straight-line curved surface structures.

4. The remote controller shell according to claim 3, wherein a straight-line generatrix forming the straight-line curved surface of the holding surface and a straight-line generatrix forming a straight-line curved surface of the control surface have an identical movement locus.

5. The remote controller shell according to claim 3, wherein the straight-line generatrix forming the straight-line curved surface of the holding surface and the straight-line generatrix forming the straight-line curved surface of the control surface have different movement loci, and wherein the movement locus of the straight-line generatrix of the straight-line curved surface of the holding surface comprises a curve segment and a straight line segment.

6. The remote controller shell according to claim 3, wherein the straight-line generatrix forming the straight-line curved surface of the holding surface and the straight-line generatrix forming the straight-line curved surface of the control surface have different movement loci, and wherein the movement locus of the straight-line generatrix of the straight-line curved surface of the control surface comprises a concave curve segment and a convex curve segment.

7. The remote controller shell according to claim 2, wherein the holding surface and the control surface are curvilinear curved surface structures.

8. The remote controller shell according to claim 7, wherein a curvilinear generatrix of a curvilinear curved surface of the holding surface and a curvilinear generatrix of a curvilinear curved surface of the control surface respectively have at least two curves connected tangentially.

9. The remote controller shell according to claim 7, wherein the curvilinear generatrix of the curvilinear curved surface of the holding surface and the curvilinear generatrix of the curvilinear curved surface of the control surface both include i) a curve and a straight line, or ii) straight lines having different slopes.

10. The remote controller shell according to claim 8, wherein the curvilinear generatrix of the curvilinear curved surface of the holding surface and the curvilinear generatrix of the curvilinear curved surface of the control surface include curves having different curvatures.

11. The remote controller shell according to claim 2, wherein one of the holding surface and the control surface is a straight-line curved surface structure, wherein the other of the holding surface and the control surface is a curvilinear curved surface structure, and wherein as a whole, the straight-line curved surface and the curvilinear curved surface have a consistent concave-convex trend.

12. The remote controller shell according to claim 1, wherein the holding surface is a plane surface structure, and wherein the control surface is a curved surface structure.

13. The remote controller shell according to claim 12, wherein the control surface is one of a straight-line curved surface structure and a curvilinear curved surface structure, and wherein a cambered surface of the straight-line curved surface or the curvilinear curved surface is inwardly concave relative to the plane surface structure.

14. The remote controller shell according to claim 1, wherein in the control surface, a curved surface radian of the curved surface structure ranges from 0 rad to π rad.

15. The remote controller shell according to claim 1, wherein an upper surface of a first function key of the at least one function key has a same curved surface curvature as that of a settings area of the control surface provided with the first function key.

16. The remote controller shell according to claim 1, wherein a contact part between a first function key of the at least one function key and a circuit board inside the shell is formed by an elastic material, and wherein i) the first function key is wholly formed of an elastic material, or ii) only a key base of the first function key in contact with the circuit board is formed of an elastic material.

17. (canceled)

18. The remote controller shell according to claim 1, wherein an upper surface of a first function key of the at least one function key is higher than a curved surface of a settings area of the control surface, and wherein a distance between the upper surface of the first function key and the curved surface of the settings area of the control surface is equal to a distance that the first function key needs to be pressed for proper functioning.

19. (canceled)

20. A remote controller, comprising the remote controller shell according to claim 1.

21. A display system, comprising the remote controller according to claim 20.

22. A control system, comprising the remote controller according to claim 20.
